(19) United States
(12) Patent Application Publication
(10) Pub. No.: US 2020/0356189 A1
(43) Pub. Date: Nov. 12, 2020

(54) SPECIAL-PURPOSE ACTIVE CAPACITIVE PEN MODULE

(71) Applicant: LING HUANG, LUODING (CN)

(72) Inventor: YUERONG WU, HEYUAN (CN)

(73) Assignee: LING HUANG

(21) Appl. No.: 16/824,686

(22) Filed: Mar. 19, 2020

(30) Foreign Application Priority Data
May 9, 2019 (CN) 201920660723.2

(51) Int. Cl. G06F 3/0354; H05K 7/14; H05K 5/02

(52) U.S. Cl. CPC G06F 3/03545; H05K 5/0217; H05K 7/1427

(57) ABSTRACT

The utility model discloses a special-purpose active capacitive pen module, which belongs to the technical field of electronic capacitive pen. It solves the problem of large writing offset and low accuracy and the problem of hand interference with pen signal faced by the existing capacitive pen. The pen core constructed by the utility model adopts two transmitting cores: Specifically, the signal circuit board is electrically connected with transmitting core A, transmitting core B and ground core. The transmitting core A is covered with the ground core, and the ground core is covered with the transmitting core B.

### CROSS-REFERENCE TO RELATED APPLICATIONS

This application claims priority to Chinese Patent Application No. 201920660723.2 with a filing date of May 9, 2019. The content of the aforementioned application, including any intervening amendments thereto, are incorporated herein by reference.

### FIELD OF TECHNOLOGY

The utility model gets involved in the technical field of electronic capacitive pen, a special-purpose active capacitive pen module in particular.

### BACKGROUND

Capacitive pen is a pen made of conductor materials, which is conductive and used to touch the capacitive screen to complete the human-computer conversation. It is an auxiliary device which imitates human body (usually fingers) through conductor materials to complete the human-computer conversation. With the development of APPs, the current capacitive pen is no longer simply replace fingers to operate, but more and more professionals have tried the active capacitive pen to work on mobile devices.

At present, the existing capacitive pen available in the market relies on absorbing screen signal and then amplifying it and returning it to the screen signal, which is a universal signal. When used on the device, the screen will always send out and receive signals, resulting in a large writing offset and low accuracy, and hand interference with pen signal, so hands cannot be placed on the screen. As signals have only one signal source, the device cannot identify whether the pen is tilted, so that it cannot make a judgment, which makes its experience effect greatly reduced and is not conductive to promotion.

### CONTENTS OF THE UTILITY MODEL

The purpose of the utility model is to provide a special-purpose active capacitive pen in order to make up the insufficiency and shortcomings of the existing technology. It adopts specified signal source, so that high-precision writing can be achieved on the specified device, which eliminates writing offset. Moreover, hands can also be placed directly on the screen without affecting pen signal, which greatly restores original handwriting, and enables the device to identify pen bevel and trigger the corresponding function.

In order to achieve the above purpose, the utility model applies the following technical plan:

The special-purpose active capacitive pen module is composed of the signal circuit board, transmitting core A, transmitting core B, ground core, metal tube, beveled support, lower support, upper support and pen cap. The pen core is composed of the described transmitting core A and transmitting core B. It is characterized that the transmitting core A is covered with the ground core and the ground core is covered with the transmitting core B. These three cores are mutually insulated. The transmitting core A is longer than the ground core, and the ground core is also longer than the transmitting core B. These three cores are stacked in a tower shape.

As a further scheme of the utility model, one end of the described transmitting core A is electrically connected with the end pin of the signal circuit on the described signal circuit board. The described ground core is covered on the described transmitting core. The surface of the described ground core is covered with an insulating layer. One end of the described ground core is electrically connected with the end pin of the ground circuit of the signal circuit board.

As a further scheme of the utility model, the described transmitting core B is covered on the described ground core. The surface of the described transmitting core B is covered with an insulating layer, which is insulated when in contact with the ground core. One end of the described transmitting core B is electrically connected with the end pin of the transmitting core circuit B on the signal circuit board.

As a further scheme of the utility model, the described ground core and transmitting core B are fixed in the slot position of the described lower support.

As a further scheme of the utility model, the described metal tube is covered on the upper and lower supports, which is electrically connected with the ground spring piece on the described signal circuit board.

As a further scheme of the utility model, the described beveled support is internally threaded, threaded, which is screwed on the thread of the upper support and the lower support and fixed on one end of the described metal tube.

As a further scheme of the utility model, the described pen cap is screwed on one end of the described beveled support through thread, and the transmitting core A is fully screwed on the internal front end of the pen cap through elastic contact.

As a further scheme of the utility model, the described upper support and the lower support are mutually fastened and are provided with a mutually fastened buckle

To sum up, the implementation plan of the utility model has the following beneficial effects compared with the existing technology:

The utility model applies reasonable design and adopts specified signal source, so that high-precision writing can be achieved on the specified device, which eliminates writing offset. Moreover, hands can also be placed directly on the screen without affecting pen signal, which greatly restores original handwriting, and enables the device to identify pen bevel and trigger the corresponding function.

### DESCRIPTION FOR FIGURES

In order to explain the implementation plan of the utility model or the technical scheme in the existing technology more clearly, the following attached figures for the implementation plan or existing technical scheme are displayed for the simple introduction. Obviously, the following figures are only some of the implementation plans of the utility model. For common technicians of the area, they can acquire the other figures according to the existing ones under the premise of not paying any creativity or labor.

FIG. 1 is the structural diagram of the implementation plan of the utility model.

FIG. 2 is the structural diagram for the installation of upper and lower supports in the implementation plan of the utility model.

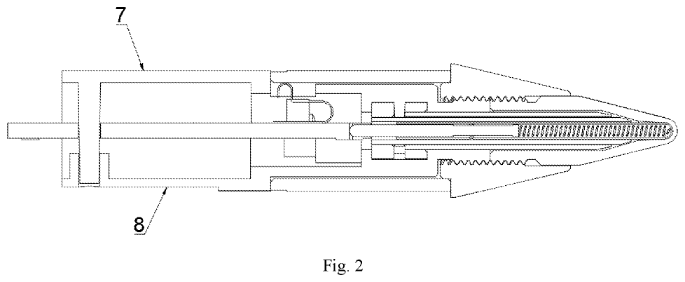

FIG. 3 is the structural diagram of the pen core in the implementation plan of the utility model.

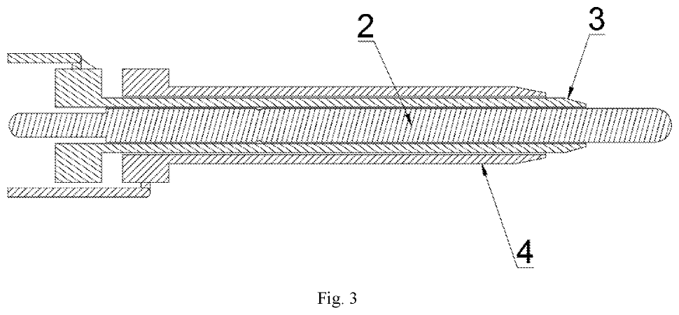

FIG. 4 is the structural diagram of the transmitting core A in the implementation plan of the utility model.

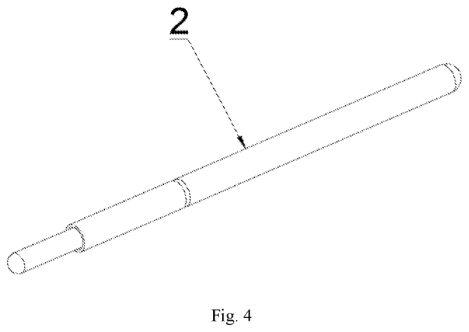

FIG. 5 is the structural diagram of the transmitting core B in the implementation plan of the utility model.

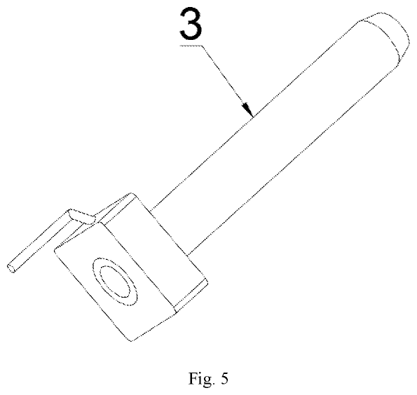

FIG. 6 is the structural diagram of the ground core in the implementation plan of the utility model.

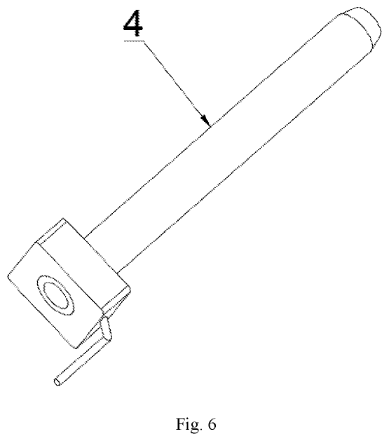

FIG. 7 is the structural diagram of the metal tube in the implementation plan of the utility model.

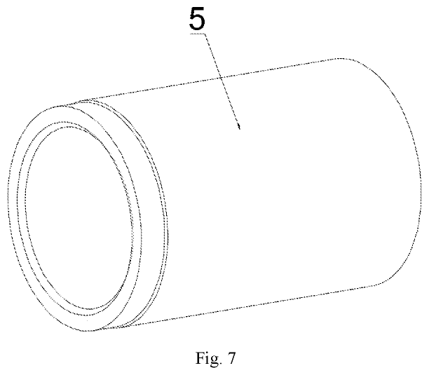

FIG. 8 is the structural diagram of the beveled support in the implementation plan of the utility model.

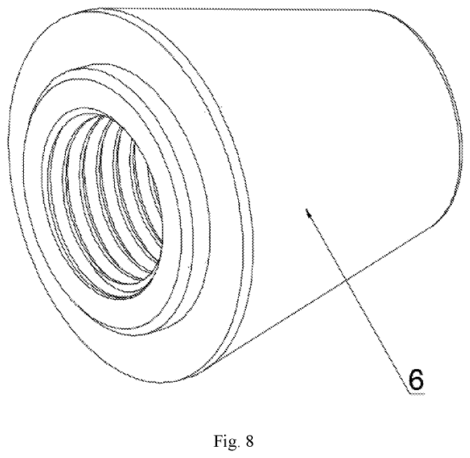

FIG. 9 is the structural diagram of the pen cap in the implementation plan of the utility model.

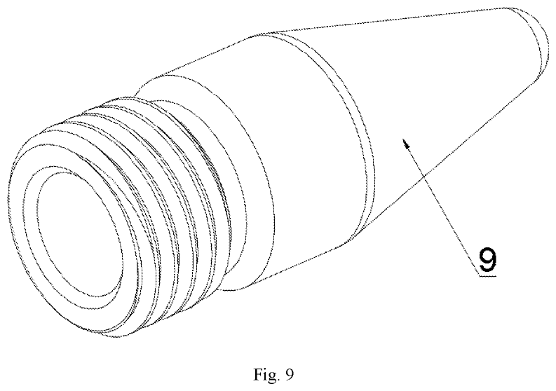

FIG. 10 is the structural diagram of the lower support in the implementation mode of the utility model.

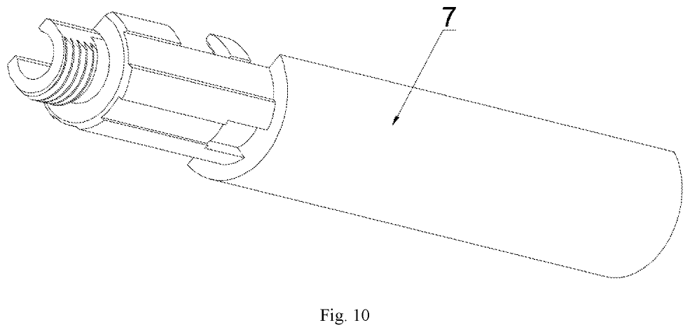

FIG. 11 is the structural diagram of the upper support in the implementation mode of the utility model.

Description of the marks of the figures: 1—signal circuit board, 2—transmitting core A, 3—transmitting core B, 4—ground core, 5—metal tube, 6—beveled support, 7—lower support, 8—upper support and 9—pen cap.

### SPECIFIC IMPLEMENTATION MODE

The technical scheme of the utility model will be further described in combination with the attached figures and specific implementation plans.

Implementation Plan 1

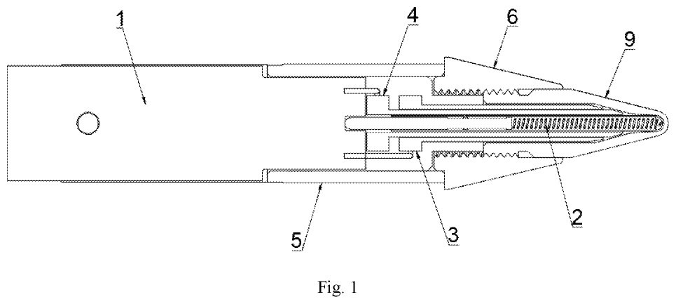

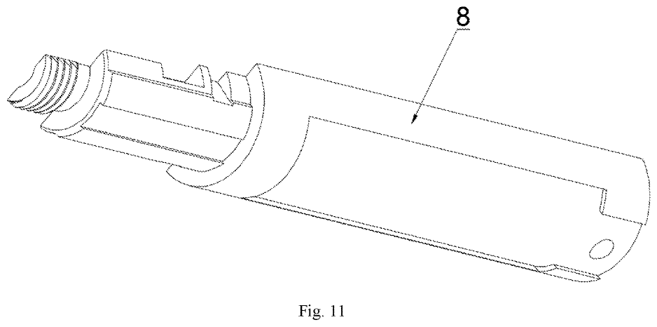

As shown in FIG. 1˜FIG. 11, the special-purpose active capacitive pen module is composed of the signal circuit board 1, transmitting core A2, transmitting core B3, ground core 4, metal tube 5, beveled support 6, lower support 7, upper support 8 and pen cap 9.

The described signal circuit board 1 is electrically connected with the transmitting core A2, transmitting core B3 and ground core 4. The transmitting core A2 is covered with the ground core 4. The ground core 4 is covered with the transmitting core B3. These three cores are mutually insulated. The transmitting core A2 is longer than the ground core 4, and the ground core 4 is also longer than the transmitting core B3. These three cores are stacked in a tower shape.

Specifically, one end of the described transmitting core A2 is electrically connected with the end pin of the signal circuit A on the described signal circuit board 1. The described ground core 4 is covered on the described transmitting core A2. The surface of the described ground core 4 is covered with an insulating layer, which is insulated when in contact with the transmitting core A2. One end of the described ground core 4 is electrically connected with the end pin of the ground circuit on the signal circuit board. The described transmitting core B3 is covered on the described ground core 4. The surface of the described transmitting core B3 is covered with an insulating layer, which is insulated when in contact with the ground core 4. One end of the described transmitting core B3 is electrically connected with the end pin of the transmitting core circuit on the signal circuit board 1. The described ground core 4 and transmitting core B3 are fixed in the slot position of the described lower support 7, so as to ensure the spacing and position of the cores described above.

The described metal tube is covered on the upper support 8 and the lower support 7, which is electrically connected with the ground spring piece on the described signal circuit board 1. The described beveled support 6 is internally threaded, which can be screwed on the thread of the upper support 8 and the lower support 7, and fixed on one end of the described metal tube 5. The described pen cap 9 is screwed on one end of the described beveled support 6 through thread. The described transmitting core A2 is fully screwed on the internal front end of the pen cap 9 through elastic contact, so as to avoid gap.

The operating principle of the utility model is that it is constructed with two transmitting cores. Specifically, specific signal A is sent out through the signal circuit board 1, and is then transmitted to the transmitting core A2 electrically connected on the circuit end pin A for signal transmission, which can be identified by the specified device. When the specified device identifies the signal, it will immediately stop the signal sent out by the device screen, and the screen will change to the mode of high-precision receipt signal. As the screen has stopped sending out the signal, hand signal will not be identified, and hands will not interfere with the use of the pen. Specific signal B is sent out through the signal circuit board 1, and is then transmitted to the transmitting core B3 electrically connected on the circuit end pin B for signal transmission, which can be identified by the specified device, so that the device can determine whether the pen is tilted according to whether it receives the signal, thus reflecting the function that should be triggered when the pen is tilted. The ground core 4 is installed between the transmitting core A2 and the transmitting core B3 to avoid mutual interference of the two signals.

Implementation Plan 2

As shown in FIG. 1˜FIG. 11, the special-purpose active capacitive pen module is composed of the signal circuit board 1, transmitting core A2, transmitting core B3, ground core 4, metal tube 5, beveled support 6, lower support 7, upper support 8 and pen cap 9.

The described upper support 8 and lower support 7 are mutually fastened and provided with a mutually fastened buckle. This implementation plan shares the same other structural parts as Implementation Plan 1.

The utility model applies reasonable design and adopts specified signal source, so that high-precision writing can be achieved on the specified device, which eliminates writing offset. Moreover, hands can also be placed directly on the screen without affecting pen signal, which greatly restores original handwriting, and enables the device to identify pen bevel and trigger the corresponding function.

The technical principle of the utility model is described above in combination with specific implementation plans, which are only the preferred implementation modes of the utility model. The protection scope of the utility model is not limited to the above implementation plans, and all technical schemes under the idea of the utility model fall within the protection scope of the utility model. For technicians of the area, they can associate with other implementation plans of the utility model without paying any creativity or labor. These plans will also fall within the protection scope of the utility model.

I claim:

1. The special-purpose active capacitive pen module comprises: the signal circuit board (1), transmitting core A (2), transmitting core B (3), ground core (4), metal tube (5), beveled support (6), lower support (7), upper support (8) and pen cap (9);
wherein, the pen core is composed of the described transmitting core A (2) and transmitting core B (3);
wherein, the transmitting core A (2) is covered with the ground core (4) and the ground core (4) is covered with the transmitting core B (3);
wherein these three cores are mutually insulated;
wherein, the transmitting core A (2) is longer than the ground core (4), and the ground core (4) is also longer than the transmitting core B (3);
wherein, these three cores are stacked in a tower shape.

2. The special-purpose active capacitive pen module according to claim 1, wherein one end of the described transmitting core A (2) is electrically connected with the end pin of signal circuit A on the described signal circuit board (1); wherein the described ground core (4) is covered on the described transmitting core A (2); wherein the surface of the described ground core (4) is covered with an insulating layer; wherein, one end of the described ground core (4) is electrically connected with the end pin of the ground circuit on the signal circuit board (1).

3. The special-purpose active capacitive pen module according to claim 2, wherein the described transmitting core B (3) is covered on the described ground core (4); wherein the surface of the described transmitting core B (3) is covered with an insulating layer, which is insulated when in contact with the ground core (4); wherein one end of the described transmitting core B (3) is electrically connected with the end pin of the transmitting core circuit B on the signal circuit board (1).

4. The special-purpose active capacitive pen module according to claim 3, wherein the described ground core (4) and the transmitting core B (3) are fixed in the slot position of the described lower support (7).

5. The special-purpose active capacitive pen module according to claim 4, wherein the described metal tube (5) is covered on the upper support (8) and the lower support (7), which is electrically connected with the ground spring piece on the described signal circuit board (1).

6. The special-purpose active capacitive pen module according to claim 5, wherein the described beveled support (6) is internally threaded, which is screwed on the thread of the upper support (8) and the lower support (7) and fixed on one end of the described metal tube (5).

7. The special-purpose active capacitive pen module according to claim 6, wherein the described pen cap (9) is screwed on one end of the described beveled support (6) through thread, and the transmitting core A (2) is fully screwed on the internal front end of the pen cap (9) through elastic contact.

8. The special-purpose active capacitive pen module according to claim 1, wherein the described upper support (8) and the lower support (7) are mutually fastened and are provided with a mutually fastened buckle.
